(19) United States
(12) Patent Application Publication
(10) Pub. No.: US 2026/0250880 A1
(43) Pub. Date: Aug. 27, 2026

(54) GALLIUM NITRIDE MULTILAYER SUBSTRATE MANUFACTURING METHOD, GALLIUM NITRIDE MULTILAYER SUBSTRATE, AND GALLIUM NITRIDE SINGLE CRYSTAL SUBSTRATE

(71) Applicant: SUMITOMO CHEMICAL COMPANY, LIMITED, Tokyo (JP)

(72) Inventors: Daiki IWATA, Ibaraki (JP); Yoshinobu NARITA, Ibaraki (JP); Masatomo SHIBATA, Ibaraki (JP)

(21) Appl. No.: 19/441,026

(22) Filed: Jan. 6, 2026

(30) Foreign Application Priority Data
Feb. 27, 2025 (JP) 2025-030590

(51) Int. Cl. C30B 25/20; C30B 25/18; C30B 29/40

(52) U.S. Cl. CPC C30B 25/20; C30B 25/186; C30B 29/406

(57) ABSTRACT

There is provided a gallium nitride multilayer substrate manufacturing method for producing a device having a pn junction, the method including: preparing an n-type gallium nitride single crystal substrate having a diameter of 50 mm or more and (0001) as a low-index crystal plane closest to a main surface; growing an n-type gallium nitride single crystal layer on the substrate; applying a dehydrogenation treatment to the multilayer substrate on which the n-type gallium nitride single crystal layer has been grown; growing a p-type gallium nitride single crystal layer on the multilayer substrate that has been subjected to the dehydrogenation treatment; and applying another dehydrogenation treatment to the multilayer substrate on which the p-type gallium nitride single crystal layer has been grown.

### BACKGROUND

### Technical Field

The present disclosure relates to a gallium nitride multilayer substrate manufacturing method, a gallium nitride multilayer substrate, and a gallium nitride single crystal substrate.

### Description of Related Art

P-type gallium nitride (GaN) is typically produced by growing a magnesium (Mg)-doped GaN crystal, followed by a dehydrogenation treatment. The dehydrogenation treatment is required because hydrogen (protons) is more likely to be incorporated into the Mg-dope GaN crystal, and the hydrogen binds to Mg and deactivates a function as an acceptor (see, for example, Patent document 1).

GaN-based pn diode, which is used as a power device, has a problem that degradation of the diode characteristics is observed when a large current is passed therethrough during a forward bias test. Also, a slight degradation of the diode characteristics is still observed during a reverse bias test (see, for example, Non-Patent document 1).

### Citation List

### Patent Documents

[Patent Document 1] Japanese Unexamined Patent Publication No. 1993-183189

[Non-Patent Document 1] T. Narita et al., Scientific Reports 12, 1458 (2022)

### SUMMARY OF THE INVENTION

### Technical Problem

One object of the present disclosure is to provide a technique for suppressing a current-induced degradation of a GaN device having a pn junction, such as a pn diode.

### Solution to Problem

According to one aspect of the present disclosure, there is provided a gallium nitride multilayer substrate manufacturing method for producing a device having a pn junction, the method including:
preparing an n-type gallium nitride single crystal substrate having a diameter of 50 mm or more and (0001) as a low-index crystal plane closest to a main surface;
growing an n-type gallium nitride single crystal layer on the substrate;
applying a dehydrogenation treatment to the multilayer substrate on which the n-type gallium nitride single crystal layer has been grown; growing a p-type gallium nitride single crystal layer on the multilayer substrate that has been subjected to the dehydrogenation treatment; and
applying another dehydrogenation treatment to the multilayer substrate on which the p-type gallium nitride single crystal layer has been grown.

According to another aspect of the present disclosure, there is provided a gallium nitride multilayer substrate for producing a device having a pn junction, the substrate having a structure in which at least an n-type gallium nitride single crystal layer and a p-type gallium nitride single crystal layer are stacked in this order on an n-type gallium nitride single crystal substrate having a diameter of 50 mm or more and (0001) as a low-index crystal plane closest to a main surface,

wherein a hydrogen concentration in at least a region 50 μm inward from the main surface of the n-type gallium nitride single crystal substrate and in the n-type gallium nitride single crystal layer is less than 5 × 10¹⁶ cm⁻³.

### Advantageous Effects of Invention

There is provided a technique for suppressing a current-induced degradation of a GaN device having a pn junction.

### BRIEF DESCRIPTION OF THE DRAWINGS

FIG. 1 is a schematic cross-sectional view showing a multilayer substrate 100 according to an embodiment of the present disclosure.

FIG. 2 is a timing chart showing a first example of a method for manufacturing the multilayer substrate 100 according to the embodiment.

FIG. 3 is a timing chart showing a second example of the method for manufacturing the multilayer substrate 100 according to the embodiment.

FIG. 4 is a timing chart showing a third example of the method for manufacturing the multilayer substrate 100 according to the embodiment.

FIG. 5 is a graph showing an example of a phenomenon in which degraded characteristics are restored by applying another dehydrogenation treatment to a GaN-based pn diode.

### DETAILED DESCRIPTION OF THE INVENTION

Before describing the embodiments of the present disclosure, the findings obtained by the present inventors will be described. As described above, in the gallium nitride (GaN)-based pn diode (hereinafter also simply referred to as a diode), the diode characteristics are degraded due to a forward current flow, etc. As a result of extensive research, the inventors of the present disclosure have found a phenomenon in which by applying another dehydrogenation treatment to a diode with degraded characteristics, the degraded characteristics are restored.

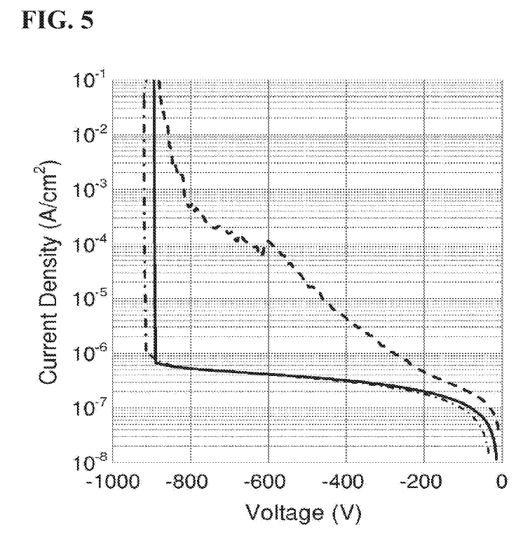

FIG. 5 is a graph showing experimental results showing an example of this phenomenon. This experiment was performed as follows. A multilayer substrate was produced having a structure in which an n-type GaN single crystal layer having a silicon (Si) concentration of 2 ×10¹⁸ cm⁻³ and a thickness of 2 μm, an n-type GaN single crystal layer having a Si concentration of 2 × 10¹⁶ cm⁻³ and a thickness of 9 μm, and a p-type GaN single crystal layer having a magnesium (Mg) concentration of 1 × 10¹⁸ cm⁻³ and a thickness of 500 nm were stacked in this order on an n-type GaN single crystal substrate. After applying a dehydrogenation treatment to the multilayer substrate, a p-side electrode was formed on the upper side of the p-type GaN single crystal layer, an n-side electrode was formed on the lower side of the n-type GaN single crystal substrate, and an insulating film was also formed as appropriate. Thus, a diode was produced.

After a current test at 1A for 1 hour was applied to the diode, the p-side electrode, the n-side electrode, and the insulating film were removed, and a heat treatment was applied to the multilayer substrate from which the electrodes and other components had been removed at 850°C for 30 minutes in a nitrogen gas atmosphere (i.e., another dehydrogenation treatment). The diode was re-produced by re-forming electrodes, etc., on the multilayer substrate that had been subjected to another dehydrogenation treatment.

The electrical characteristics of the diode were evaluated three times: before the current test, after the current test, and after re-production (after another dehydrogenation treatment). The current test was performed under a condition that a current of 1A was passed through a device having an electrode diameter of Φ400 μm for 1 hour. For the evaluation of the electrical characteristics, forward IV measurement and reverse IV measurement were performed. FIG. 5 shows the results of the reverse IV measurement obtained from these three measurements. The solid line shows the results before the current test, the dashed line shows the results after the current test, and the dash-dot line shows the results after re-production.

The measurement before the current test showed that the current density of the reverse leakage current was suppressed to 10⁻⁶A/cm² or less from an applied voltage of 0 V to about -900 V, and breakdown occurred at about -900V. In contrast, the measurement after the current test showed a significant increase in the reverse leakage current, with the current density of the reverse leakage current reaching 10⁻⁶ A/cm² at an applied voltage of about -300 V and exceeding 10⁻⁴ A/cm² at about -800 V. That is, the forward current flow causes degradation of the diode characteristics. It has also been found that the reverse bias test also reveals a slight degradation of the diode characteristics.

However, the measurement after re-production, that is, the measurement of a diode that has been subjected to another dehydrogenation treatment after degradation showed that, similarly to the case before the current test, the current density of the reverse leakage current was suppressed to 10⁻⁶ A/cm² or less from the applied voltage of 0 V to about -900 V, and breakdown occurred at about -900 V. Thus, it was found that the diode characteristics were restored by applying another dehydrogenation treatment.

Based on this phenomenon, the inventors of the present disclosure have investigated the mechanism of current degradation in diodes and found that the cause is hydrogen diffusion from the n-type GaN single crystal layer that underlies the p-type GaN single crystal layer. Specifically, it was found that as the device temperature rises while current is flowing, hydrogen in the n-type GaN single crystal layer or the n-type GaN single crystal substrate penetrates into the p-type GaN single crystal by anomalous diffusion via dislocation cores, and binds with Mg, thereby deactivating the p-type layer.

Almost all of the underlying GaN single crystal substrates available on the market are grown by the HVPE method. Further, the MOCVD method is generally used as a technique for growing the n-type GaN single crystal layer on the substrate. In these growth methods, ammonia is used as a nitrogen source, and the n-type GaN crystal (produced by conventional technique) contains 5 × 10¹⁶ cm⁻³ or more of hydrogen derived from ammonia, although not as much as in the p-type GaN crystal.

In the pn junction such as those in currently popular light-emitting devices, the hydrogen in the substrate or the n-type GaN layer does not degrade the device characteristics. However, the present inventors have found for the first time that in devices such as GaN power devices, in which high voltage is applied and large current flows, the hydrogen in the substrate or the n-type GaN layer degrades the device characteristics.

Based on this finding, the following describes, as an embodiment of the present disclosure, a technique for suppressing hydrogen diffusion into the p-type GaN single crystal layer by reducing the hydrogen concentration on the n-type GaN single crystal layer side that underlies the p-type GaN single crystal layer.

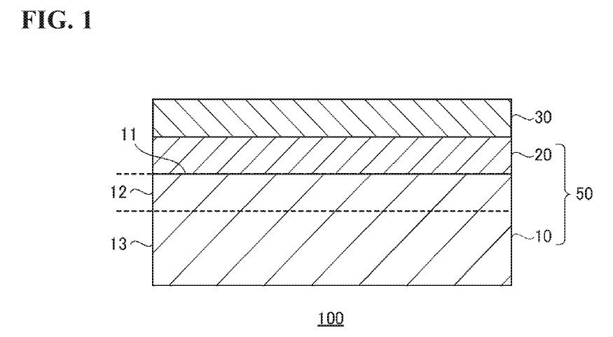

A GaN multilayer substrate 100 (hereinafter also simply referred to as a multilayer substrate 100) according to an embodiment of the present disclosure will be described. FIG. 1 is a schematic cross-sectional view showing the multilayer substrate 100. The multilayer substrate 100 has a structure in which at least an n-type GaN single crystal layer 20 (hereinafter also simply referred to as an n-type layer 20) and a p-type GaN single crystal layer 30 (hereinafter also simply referred to as a p-type layer 30) are stacked in this order on an n-type GaN single crystal substrate 10 (hereinafter also simply referred to as a substrate 10), and is used as a material for producing a device having a pn junction, preferably a power device.

The substrate 10 is composed of a GaN single crystal doped with Si or germanium (Ge) as an n-type impurity, has a diameter of 50 mm or more, a thickness of 300 μm or more, and has a main surface 11 that serves as a base for growing the n-type layer 20. The (0001) is a low-index crystal plane closest to the main surface 11. The n-type impurity concentration (total concentration of Si and Ge) in the substrate 10 is, for example, 1 × 10¹⁸ cm⁻³ or more and 3 × 10¹⁹ cm⁻³ or less.

The n-type layer 20 is composed of a GaN single crystal epitaxially grown on the substrate 10 (on the main surface 11) and doped with Si or Ge as an n-type impurity. The n-type layer 20 is stacked on the substrate 10 to form a GaN multilayer substrate 50 (which is an intermediate structure of the multilayer substrate 100). The thickness of the n-type layer 20 is, for example, 4 μm or more and 30 μm or less. The n-type layer 20 may be configured by stacking a plurality of layers having different n-type impurity concentrations. Specifically, similarly to the above-described experiment, the n-type layer 20 is given as an example, that is formed by stacking a lower layer (layer on the substrate 10 side) having a relatively high Si concentration (e.g., 2 × 10¹⁸ cm⁻³) and an upper layer (layer on the p-type layer 30 side) having a relatively low Si concentration (e.g., 2 × 10¹⁶ cm⁻³).

The n-type layer 20 has at least a layer with a relatively low concentration of n-type impurities immediately below the p-type layer 30 in order to increase breakdown voltage of the pn junction. In the n-type layer 20, the n-type impurity concentration (total concentration of Si and Ge) in the layer with a relatively low n-type impurity concentration is, for example, 4 × 10¹⁵ cm⁻³ or more and 2 × 10¹⁶ cm⁻³ or less.

The p-type layer 30 is a layer that forms a pn junction at the interface with the n-type layer 20, and is composed of GaN single crystal epitaxially grown on the n-type layer 20 and doped with Mg as a p-type impurity. The thickness of the p-type layer 30 is, for example, 0.2 μm or more and 1.5 μm or less. The p-type impurity concentration (Mg concentration) in the p-type layer 30 is, for example, 1 × 10¹⁷ cm⁻³ or more and less than 1 × 10²⁰ cm⁻³. From the viewpoint of improving the crystal quality of the p-type layer 30 and forming a good pn junction, the p-type impurity concentration (Mg concentration) in the p-type layer 30 is preferably less than 1 × 10²⁰ cm⁻³.

On the p-type layer 30 (for forming the pn junction with the n-type layer 20), a layer doped with Mg at a high concentration of 1 × 10²⁰ cm⁻³ or more (p+ type layer) may be formed as a contact layer interposed between the p-type layer 30 and a p-side electrode.

The substrate 10 is grown by, for example, the HVPE method. The n-type layer 20 and the p-type layer 30 are grown by, for example, MOCVD. As described above, in these growth methods, ammonia is used as a nitrogen source, and therefore, in the conventional technique, the substrate 10 and the n-type layer 20 contain hydrogen derived from ammonia at a concentration of 5 × 10¹⁶ cm⁻³ or more. The p-type layer 30 is more likely to incorporate hydrogen due to doping with Mg, and therefore has a hydrogen concentration of about 1 × 10¹⁷ cm⁻³ or more (even after dehydrogenation treatment).

In contrast, in the multilayer substrate 100 according to this embodiment, the hydrogen concentration in the n-type layer 20 is reduced to less than 5 × 10¹⁶ cm⁻³. Further, the hydrogen concentration in (at least) the surface layer 12 of the substrate 10 (in a region 50 μm inward in thickness from the main surface 11) is preferably reduced to less than 5 × 10¹⁶ cm⁻³. The hydrogen concentration in the n-type layer 20 and the hydrogen concentration in the surface layer 12 of the substrate 10 are each preferably 1 × 10¹⁶ cm⁻³ or less, and more preferably 7 × 10¹⁵ cm⁻³ or less. A method for reducing the hydrogen concentration in the n-type layer 20 and the substrate 10 will be described later.

Since the substrate 10, which is a freestanding substrate, is thick, the hydrogen concentration does not need to be reduced to less than 5 × 10¹⁶ cm⁻³ over an entire thickness. That is, the hydrogen concentration in a lower layer portion 13 on the lower side of a surface layer portion 12 (opposite side of the n-type layer 20) may be 5 × 10¹⁶ cm⁻³ or more. In this embodiment, the hydrogen concentration in the GaN single crystal that constitutes the substrate 10 has a gradient distribution that gradually increases from the main surface 11 toward the thickness direction of the substrate 10.

The hydrogen concentration is measured by secondary ion mass spectrometry (SIMS). The hydrogen concentration in the n-type layer 20 being reduced to less than 5 × 10¹⁶ cm⁻³ means that an average hydrogen concentration in the thickness direction over the entire thickness of the n-type layer 20 is less than 5 × 10¹⁶ cm⁻³. Further, the hydrogen concentration in the surface layer 12 of the substrate 10 (in a region 50 μm inward from the main surface 11) being reduced to less than 5 × 10¹⁶ cm⁻³ means that an average hydrogen concentration in the thickness direction of the surface layer 12 of the substrate 10 (in a region 50 μm inward from the main surface 11) is less than 5 × 10¹⁶ cm⁻³. The same applies to the hydrogen concentration of 1 × 10¹⁶ cm⁻³ or less and 7 × 10¹⁵ cm⁻³ or less. The lower limit of hydrogen detection by SIMS (when using the raster variation method) is approximately 7 × 10¹⁵ cm⁻³.

In the multilayer substrate 100 according to this embodiment, the hydrogen concentration in the n-type layer 20 disposed directly under the p-type layer 30 is reduced to less than 5 × 10¹⁶ cm⁻³ (preferably 1 × 10¹⁶ cm⁻³ or less, and more preferably 7 × 10¹⁵ cm⁻³ or less), thereby suppressing hydrogen diffusion into the p-type layer 30. This makes it possible to suppress the current-induced degradation of the GaN device having a pn junction, which is produced using the multilayer substrate 100. Further, preferably, the hydrogen concentration in the surface layer 12 of the substrate 10 disposed below the n-type layer 20 is also reduced to less than 5 × 10¹⁶ cm⁻³ (preferably 1 × 10¹⁶ cm⁻³ or less, and more preferably 7 × 10¹⁵ cm⁻³ or less), thereby further suppressing the hydrogen diffusion into the p-type layer 30 and further suppressing the degradation of the GaN device.

Thus, according to this embodiment, the multilayer substrate 100 composed of the substrate 10, the n-type layer 20 and the p-type layer 30, and the multilayer substrate 50 composed of the substrate 10 and the n-type layer 20 are provided, or the substrate 10 is provided. This is suitable for suppressing the hydrogen diffusion into the p-type layer 30.

Next, a method for manufacturing the multilayer substrate 100 according to the embodiment of the present disclosure (a method for reducing the hydrogen concentration in the n-type layer 20 and the substrate 10) will be described. The multilayer substrate 100 is formed by growing the n-type layer 20 and the p-type layer 30 on the substrate 10. The n-type layer 20 and the p-type layer 30 are grown by, for example, MOCVD.

As a Ga source, for example, trimethylgallium (TMG) is used. As an N source, a hydrogen compound of nitrogen, for example, ammonia (NH₃), is used. As an n-type impurity source, for example, silane (SiH₄) or germane (GeH₄) is used. As a p-type impurity source, for example, biscyclopentadienyl magnesium (Cp₂Mg) is used. As a carrier gas, for example, nitrogen (N₂) gas is used. The growth temperature of GaN can be selected, for example, in a range of 900°C or more and 1400° C or less, and the V/III ratio, which is a flow rate ratio of the N source gas to the Ga source gas, can be selected, for example, in a range of 10 or more and 5000 or less.

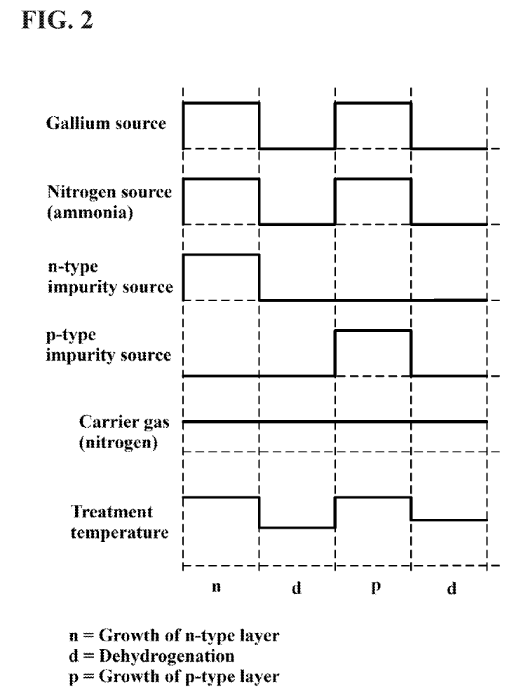

In the method for manufacturing the multilayer substrate 100 of this embodiment, in addition to the growth treatment for the n-type layer 20 and the p-type layer 30, a dehydrogenation treatment is applied to the n-type layer 20 etc., as described below. FIGS. 2, 3, and 4 are timing charts showing a first example, a second example, and a third example of the method for manufacturing the multilayer substrate 100 according to the embodiment, respectively.

A first example of the manufacturing method will be described with reference to FIG. 2. The substrate 10 is prepared, and the Ga source, N source, and n-type impurity source are supplied onto the substrate 10 to grow the n-type layer 20 (to form the multilayer substrate 50). The growth temperature is, for example, 1100°C.

The growth time is set appropriately depending on the thickness of the n-type layer 20 to be formed. Hydrogen contained in ammonia, which is the N source, is mixed into the grown n-type layer 20. When the n-type layer 20 is configured by stacking multiple layers with different n-type impurity concentrations, the supply amount of the n-type impurity source may be adjusted according to the n-type impurity concentration in each layer.

Next, the dehydrogenation treatment is applied to the n-type layer 20 (the multilayer substrate 50). The dehydrogenation treatment to the n-type layer 20 is performed by heating the multilayer substrate 50 to 500° C or higher (900° C or lower) in a hydrogen-free atmosphere and keeping the temperature for 30 minutes or longer. In this example, after the growth treatment for the n-type layer 20, (along with stop of the supply of the Ga source and supply of the n-type impurity source), the supply of ammonia (N source) serving as a hydrogen source is stopped, and the heat treatment is performed in an atmosphere of nitrogen as a carrier gas. Thus, the dehydrogenation treatment is applied to the n-type layer 20.

The temperature for the dehydrogenation treatment for the n-type layer 20 is, for example, 600°C. Since the temperature for the dehydrogenation treatment is lower than the temperature for the growth treatment for the n-type layer 20, the heat treatment is performed by lowering the treatment temperature from the temperature for the growth treatment to the temperature for the dehydrogenation treatment. The specific temperature and time for the dehydrogenation treatment for the n-type layer 20 may be appropriately determined experimentally so that the hydrogen concentration in the n-type layer 20 is reduced to less than 5 × 10¹⁶ cm⁻³ (preferably 1 × 10¹⁶ cm⁻³ or less, and more preferably 7 × 10¹⁵ cm⁻³ or less).

Next, along with supply of the Ga source and the N source, the p-type impurity source is supplied onto the multilayer substrate 50 after the dehydrogenation treatment for the n-type layer 20, to thereby grow the p-type layer 30 (form the multilayer substrate 100). The growth temperature is, for example, 1100°C. The growth time is set appropriately depending on the thickness of the p-type layer 30 to be formed. Hydrogen contained in ammonia, which is the N source, is mixed into the grown p-type layer 30. When forming a p+ type layer on the p-type layer 30, after the growth of the p-type layer 30, the supply amount of the Ga source may be reduced or the supply amount of the p-type impurity source may be increased depending on the p-type impurity concentration in the p+ type layer, and the p+ type layer may then be grown.

Next, the dehydrogenation treatment (activation treatment) is applied to the p-type layer 30 (the multilayer substrate 100). The dehydrogenation treatment is applied to the p-type layer 30 by heating the multilayer substrate 100 to 500° C or higher (900° C or lower) in a hydrogen-free atmosphere and keeping the temperature for 30 minutes or longer. In this example, after applying the growth treatment to the p-type layer 30, (along with stop of the supply of the Ga source and supply of the p-type impurity source), supply of ammonia (N source) serving as a hydrogen source is stopped, and the heat treatment is performed in an atmosphere of nitrogen as a carrier gas. Thus, the dehydrogenation treatment is performed.

The temperature for the dehydrogenation treatment for the p-type layer 30 is, for example, 850°C. Since the temperature for the dehydrogenation treatment is lower than the temperature for the growth treatment for the p-type layer 30, the heat treatment is performed by lowering the treatment temperature from the temperature for the growth treatment to the temperature for the dehydrogenation treatment. The specific temperature and time for the dehydrogenation treatment for the p-type layer 30 may be appropriately determined experimentally so that the p-type layer 30 is activated.

FIG. 2 shows an example in which after growth of the p-type layer 30, the dehydrogenation treatment is applied to the p-type layer 30 in the atmosphere of nitrogen as a carrier gas (inside of the processing chamber of the crystal growth apparatus). However, the multilayer substrate 100 may be unloaded from the crystal growth apparatus after growth of the p-type layer 30, and the dehydrogenation may be performed in another apparatus.

In this example, the growth treatment for the n-type layer 20 and the growth treatment for the p-type layer 30 are preferably performed consecutively (without exposure to the atmosphere in between) in the same processing chamber. This is to prevent contamination of a pn junction interface. On the other hand, this example is characterized in that after the n-type layer 20 is grown, the crystal growth treatment is temporarily interrupted, then the dehydrogenation treatment is applied to the n-type layer 20, and then the growth treatment for the p-type layer 30 is resumed. Therefore, from the viewpoint of preventing contamination of the surface of the n-type layer 20, it is preferable that the growth treatment for the n-type layer 20, the dehydrogenation treatment for the n-type layer 20, and the growth treatment for the p-type layer 30 are performed consecutively in the same processing chamber as that used for the growth of the n-type layer 20.

That is, after the growth of the n-type layer 20, it is preferable to set the temperature in the processing chamber to the temperature for the dehydrogenation treatment, replace the atmospheric gas with a gas that does not contain hydrogen, such as nitrogen, and perform a heat treatment for dehydrogenation, and then return the atmosphere and temperature to the crystal growth conditions again to grow the p-type layer 30. If necessary, the multilayer substrate 50 after the growth of the n-type layer 20 may be temporarily removed from the processing chamber of the crystal growth apparatus, and subjected to the dehydrogenation treatment using a dedicated heat treatment device, etc. Then, the multilayer substrate 50 may be returned to the processing chamber of the crystal growth apparatus to grow the p-type layer 30.

The temperature for the dehydrogenation treatment for the n-type layer 20 may be the same as the temperature for the dehydrogenation treatment for the p-type layer 30, but it is preferable that it be lower than the temperature for the dehydrogenation treatment for the p-type layer 30 from the viewpoint of suppressing roughening of the surface of the n-type layer 20 (the base for the growth of the p-type layer 30) due to thermal etching. Further, since the time required for the dehydrogenation treatment for the n-type layer 20 is determined depending on the thickness of the n-type layer 20, it is preferable to experimentally determine the conditions required for the dehydrogenation treatment in advance.

The hydrogen concentration in the n-type layer 20 after the dehydrogenation treatment is preferably sufficiently lower than the hydrogen concentration in the p-type layer 30 after the activation treatment. Although the specific value of the hydrogen concentration in the p-type layer 30 after activation treatment also depends on the Mg concentration, the hydrogen concentration in the n-type layer 20 is reduced compared to a conventional technique of at least 5 × 10¹⁶ cm⁻³ or more, in other words, reduced to less than 5 × 10¹⁶ cm⁻³ (it may be reduced to 3 × 10¹⁶ cm⁻³ or less, from the viewpoint of making the reduction more clear compared to 5 × 10¹⁶ cm⁻³ or more). To ensure the above-described effects, the hydrogen concentration in the n-type layer 20 is preferably reduced to 1 × 10¹⁶ cm⁻³ or less, and more preferably to 7 × 10¹⁵ cm⁻³ or less. Such conditions are the same in the case of the surface layer 12 of the substrate 10.

Although nitrogen gas is shown as a carrier gas, hydrogen (H₂) gas may be used together with the nitrogen gas as the carrier gas, if necessary. However, when the hydrogen gas is used as the carrier gas, the supply of the hydrogen gas serving as the hydrogen source is stopped during the dehydrogenation treatment.

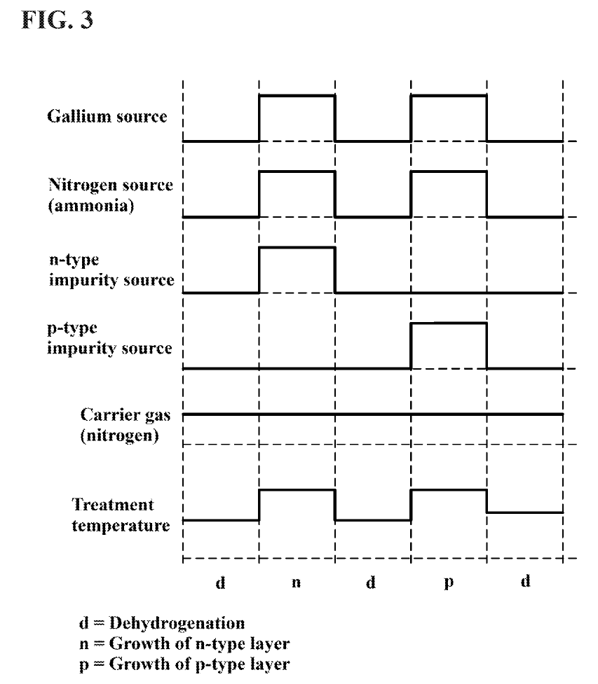

A second example of the manufacturing method will be described with reference to FIG. 3. The second example shows an embodiment in which the dehydrogenation treatment for the substrate 10 is added before the growth treatment for the n-type layer 20 of the first example. The treatment after the growth treatment for the n-type layer 20 is the same as the first example.

The dehydrogenation treatment for the substrate 10 is performed by heating the substrate 10 to 500°C or higher (900°C or lower) in an atmosphere that does not contain hydrogen and keeping the temperature for 30 minutes or longer. The temperature for the dehydrogenation treatment for the substrate 10 is, for example, 600°C. The specific temperature and time for the dehydrogenation treatment for the substrate 10 may be appropriately set experimentally so that the hydrogen concentration in the surface layer 12 of the substrate 10 is reduced to less than 5 × 10¹⁶ cm⁻³ (preferably to 1 × 10¹⁶ cm⁻³ or less, and more preferably 7 × 10¹⁵ cm⁻³ or less).

FIG. 3 shows an embodiment in which the dehydrogenation treatment is applied to the substrate 10 in the atmosphere of nitrogen as a carrier gas (in the processing chamber of the crystal growth apparatus) before the growth of the n-type layer 20. Alternatively, it is also acceptable to employ an embodiment in which the dehydrogenation treatment is applied to the substrate 10 using another device (or in the atmosphere) before being loaded into the crystal growth apparatus, and the substrate 10 that has been subjected to the dehydrogenation treatment is then loaded into the crystal growth apparatus to begin growth of the n-type layer 20.

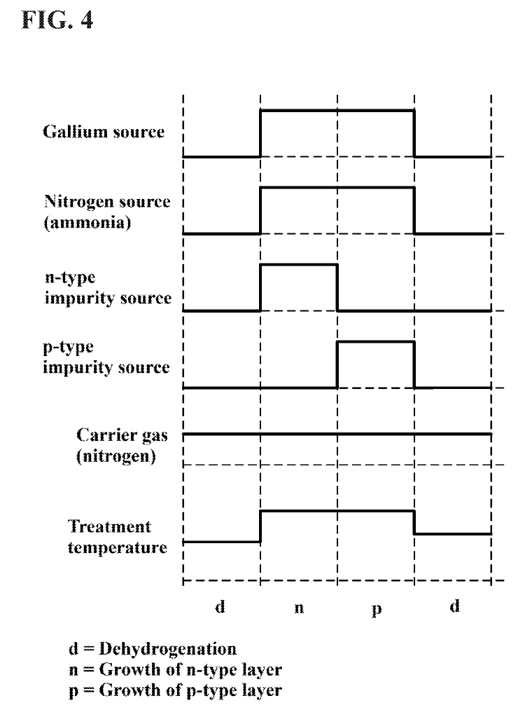

A third example of the manufacturing method will be described with reference to FIG. 4. The third example is an embodiment in which the dehydrogenation treatment for the n-type layer 20 in the second example is (formally) omitted. First, similarly to the second example, the dehydrogenation treatment is applied to the substrate 10 and the growth treatment is applied to the n-type layer 20, and then the growth treatment is applied to the p-type layer 30.

After the growth of the p-type layer 30, the dehydrogenation treatment is performed. In the third example, the dehydrogenation treatment after growth of the p-type layer 30 is performed so as to serve both as the dehydrogenation treatment for the n-type layer 20 and as the dehydrogenation treatment (activation treatment) of the p-type layer 30. Specifically, compared to the dehydrogenation treatment for only the p-type layer 30 as in the first and second examples, the treatment is performed for a long time so that the dehydrogenation treatment for the n-type layer 20 is also performed sufficiently. The specific temperature and time for the dehydrogenation treatment for the n-type layer 20 and the p-type layer 30 may be experimentally determined as appropriate so that the hydrogen concentration in the n-type layer 20 is reduced to less than 5 × 10¹⁶ cm⁻³ (preferably to 1 × 10¹⁶ cm⁻³ or less, and more preferably to 7 × 10¹⁵ cm⁻³ or less), and the p-type layer 30 is activated.

As in the second example, it is preferable to apply the dehydrogenation treatments to the substrate 10, the n-type layer 20, and the p-type layer 30 separately, but as in the third example, after applying the dehydrogenation treatment to the substrate 10, the dehydrogenation treatment may be applied to both the n-type layer 20 and the p-type layer 30.

### Preferable aspects of the present disclosure

Preferable aspects of the present disclosure will be described below.

### Supplementary description 1

A gallium nitride multilayer substrate manufacturing method for producing a device having a pn junction, the method including:

preparing an n-type gallium nitride single crystal substrate having a diameter of 50 mm or more and (0001) as a low-index crystal plane closest to a main surface;

growing an n-type gallium nitride single crystal layer on the substrate;

applying a dehydrogenation treatment to the multilayer substrate on which the n-type gallium nitride single crystal layer has been grown;

growing a p-type gallium nitride single crystal layer on the multilayer substrate that has been subjected to the dehydrogenation treatment; and

applying another dehydrogenation treatment to the multilayer substrate on which the p-type gallium nitride single crystal layer has been grown.

### Supplementary description 2

The gallium nitride multilayer substrate manufacturing method according to supplementary description 1,

wherein the dehydrogenation treatment is applied to the n-type gallium nitride single crystal substrate before growing the n-type gallium nitride single crystal layer.

### Supplementary description 3

The gallium nitride multilayer substrate manufacturing method according to supplementary description 1, wherein,

growing the n-type gallium nitride single crystal layer on the substrate;

applying the dehydrogenation treatment to the multilayer substrate on which the n-type gallium nitride single crystal layer has been grown; and

growing the p-type gallium nitride single crystal layer on the multilayer substrate that has been subjected to the dehydrogenation treatment,

are performed consecutively in the same processing chamber.

### Supplementary description 4

The gallium nitride multilayer substrate manufacturing method according to supplementary description 1,

wherein a treatment temperature for the dehydrogenation treatment applied to the multilayer substrate on which the n-type gallium nitride single crystal layer has been grown, is lower than a treatment temperature for the dehydrogenation treatment applied to the multilayer substrate on which the p-type gallium nitride single crystal layer has been grown.

### Supplementary description 5

The gallium nitride multilayer substrate manufacturing method according to supplementary description 1,

wherein after the dehydrogenation treatment is applied to the multilayer substrate on which the p-type gallium nitride single crystal layer has been grown, a hydrogen concentration in the n-type gallium nitride single crystal layer is less than 5 × 10¹⁶ cm⁻³ (preferably 1 × 10¹⁶ cm⁻³ or less, and more preferably 7 × 10¹⁵ cm⁻³ or less).

### Supplementary description 6

The gallium nitride multilayer substrate manufacturing method according to supplementary description 2,

wherein after the dehydrogenation treatment is applied to the multilayer substrate on which the p-type gallium nitride single crystal layer has been grown, a hydrogen concentration in a region 50 μm inward in thickness from the main surface of the n-type gallium nitride single crystal substrate is less than 5 × 10¹⁶ cm⁻³ (preferably 1 × 10¹⁶ cm⁻³ or less, and more preferably 7 × 10¹⁵ cm⁻³ or less).

### Supplementary description 7

A gallium nitride multilayer substrate manufacturing method for producing a device having a pn junction, the method including:

preparing an n-type gallium nitride single crystal substrate having a diameter of 50 mm or more and (0001) as a low-index crystal plane closest to a main surface;

applying a dehydrogenation treatment to the n-type gallium nitride single crystal substrate;

growing an n-type gallium nitride single crystal layer on the substrate that has been subjected to the dehydrogenation treatment;

growing a p-type gallium nitride single crystal layer on the multilayer substrate on which the n-type gallium nitride single crystal layer has been grown; and

applying another dehydrogenation treatment to the multilayer substrate on which the p-type gallium nitride single crystal layer has been grown.

### Supplementary description 8

The gallium nitride multilayer substrate manufacturing method according to supplementary description 7,

wherein after the dehydrogenation treatment is applied to the multilayer substrate on which the p-type gallium nitride single crystal layer has been grown, a hydrogen concentration in the n-type gallium nitride single crystal layer is less than 5 × 10¹⁶ cm⁻³ (preferably 1 × 10¹⁶ cm⁻³ or less, and more preferably 7 × 10¹⁵ cm⁻³ or less).

### Supplementary description 9

The gallium nitride multilayer substrate manufacturing method according to supplementary description 7,

after the dehydrogenation treatment is applied to the multilayer substrate on which the p-type gallium nitride single crystal layer has been grown, a hydrogen concentration in a region 50 μm inward in thickness from the main surface of the n-type gallium nitride single crystal substrate is less than 5 × 10¹⁶ cm⁻³ (preferably 1 × 10¹⁶ cm⁻³ or less, and more preferably 7 × 10¹⁵ cm⁻³ or less).

### Supplementary description 10

The gallium nitride multilayer substrate manufacturing method according to any one of supplementary descriptions 1 to 9,

wherein the dehydrogenation treatment is performed by heating the multilayer substrate to 500°C or higher in a hydrogen-free atmosphere and keeping the temperature for 30 minutes or longer.

### Supplementary description 11

A gallium nitride multilayer substrate having a structure in which at least an n-type gallium nitride single crystal layer and a p-type gallium nitride single crystal layer are stacked in this order on an n-type gallium nitride single crystal substrate having a diameter of 50 mm or more and (0001) as a low-index crystal plane closest to a main surface,

wherein a hydrogen concentration in at least a region 50 μm inward from the main surface of the n-type gallium nitride single crystal substrate and in the n-type gallium nitride single crystal layer is less than 5 × 10¹⁶ cm⁻³ (preferably 1 × 10¹⁶ cm⁻³ or less, more preferably 7 × 10¹⁵ cm⁻³ or less).

### Supplementary description 12

The gallium nitride multilayer substrate according to supplementary description 11,

wherein n-type impurity contained in the n-type gallium nitride single crystal substrate and n-type impurity contained in the n-type gallium nitride single crystal layer are silicon or germanium, and p-type impurity contained in the p-type gallium nitride single crystal layer is magnesium.

### Supplementary description 13

A gallium nitride single crystal substrate having a structure in which at least an n-type gallium nitride single crystal layer is stacked on an n-type gallium nitride single crystal substrate having a diameter of 50 mm or more and (0001) as a low-index crystal plane closest to a main surface,

wherein a hydrogen concentration in a region 50 μm inward from the main surface of the n-type gallium nitride single crystal substrate and a hydrogen concentration in the crystal of the n-type gallium nitride single crystal layer are both less than 5 × 10¹⁶ cm⁻³ (preferably 1 × 10¹⁶ cm⁻³ or less, and more preferably 7 × 10¹⁵ cm⁻³ or less).

### Supplementary description 14

A gallium nitride single crystal substrate,

that is an n-type gallium nitride single crystal substrate having a diameter of 50 mm or more, a thickness of 300 μm or more, and (0001) as a low-index crystal plane closest to a main surface,

wherein a hydrogen concentration in the gallium nitride single crystal has a gradient distribution that gradually increases from the main surface toward a thickness direction of the substrate, and

a hydrogen concentration in a region 50 μm inward from the main surface is less than 5 × 10¹⁶ cm⁻³ (preferably 1 × 10¹⁶ cm⁻³ or less, more preferably 7 × 10¹⁵ cm⁻³ or less).

1. A gallium nitride multilayer substrate manufacturing method for producing a device having a pn junction, the method including:
preparing an n-type gallium nitride single crystal substrate having a diameter of 50 mm or more and (0001) as a low-index crystal plane closest to a main surface;
growing an n-type gallium nitride single crystal layer on the substrate;
applying a dehydrogenation treatment to the multilayer substrate on which the n-type gallium nitride single crystal layer has been grown;
growing a p-type gallium nitride single crystal layer on the multilayer substrate that has been subjected to the dehydrogenation treatment; and
applying another dehydrogenation treatment to the multilayer substrate on which the p-type gallium nitride single crystal layer has been grown.

2. The gallium nitride multilayer substrate manufacturing method according to claim 1,
wherein the dehydrogenation treatment is applied to the n-type gallium nitride single crystal substrate before growing the n-type gallium nitride single crystal layer.

3. A gallium nitride multilayer substrate manufacturing method for producing a device having a pn junction, the method including:
preparing an n-type gallium nitride single crystal substrate having a diameter of 50 mm or more and (0001) as a low-index crystal plane closest to a main surface;
applying a dehydrogenation treatment to the multilayer substrate on which the n-type gallium nitride single crystal layer has been grown;
growing an n-type gallium nitride single crystal layer on the substrate that has been subjected to the dehydrogenation treatment;
growing a p-type gallium nitride single crystal layer on the multilayer substrate on which the n-type gallium nitride single crystal layer has been grown; and
applying another dehydrogenation treatment to the multilayer substrate on which the p-type gallium nitride single crystal layer has been grown.

4. The gallium nitride multilayer substrate manufacturing method according to claim 1, wherein the dehydrogenation treatment is performed by heating the multilayer substrate to 500° C or higher in a hydrogen-free atmosphere and keeping the temperature for 30 minutes or longer.

5. The gallium nitride multilayer substrate manufacturing method according to claim 2, wherein the dehydrogenation treatment is performed by heating the multilayer substrate to 500° C or higher in a hydrogen-free atmosphere and keeping the temperature for 30 minutes or longer.

6. . The gallium nitride multilayer substrate manufacturing method according to claim 3, wherein the dehydrogenation treatment is performed by heating the multilayer substrate to 500° C or higher in a hydrogen-free atmosphere and keeping the temperature for 30 minutes or longer.

7. A gallium nitride multilayer substrate for producing a device having a pn junction, having a structure in which at least an n-type gallium nitride single crystal layer and a p-type gallium nitride single crystal layer are stacked in this order on an n-type gallium nitride single crystal substrate having a diameter of 50 mm or more and (0001) as a low-index crystal plane closest to a main surface,
wherein a hydrogen concentration in at least a region 50 μm inward from the main surface of the n-type gallium nitride single crystal substrate and in the n-type gallium nitride single crystal layer is less than 5 × 10¹⁶ cm⁻³.

8. The gallium nitride multilayer substrate for producing a device having a pn junction according to claim 7,
wherein at least in a region 50 μm inward from the main surface of the n-type gallium nitride single crystal substrate and in the n-type gallium nitride single crystal layer, a hydrogen concentration is 1 × 10¹⁶ cm⁻³ or less.

9. The gallium nitride multilayer substrate for producing a device having a pn junction according to claim 7,
wherein at least in a region 50 μm inward from the main surface of the n-type gallium nitride single crystal substrate and in the n-type gallium nitride single crystal layer, a hydrogen concentration is 7 × 10¹⁵ cm⁻³ or less.
